(19) United States
(12) Patent Application Publication
(10) Pub. No.: US 2024/0355781 A1
(43) Pub. Date: Oct. 24, 2024

(54) INTEGRATED DEVICE COMPRISING AN OFFSET INTERCONNECT

(71) Applicant: QUALCOMM Incorporated, San Diego, CA (US)

(72) Inventors: Yangyang SUN, San Diego, CA (US); Xuefeng ZHANG, San Diego, CA (US); Jun CHEN, San Diego, CA (US); Lily ZHAO, San Diego, CA (US)

(21) Appl. No.: 18/628,469

(22) Filed: Apr. 5, 2024

Related U.S. Application Data
(60) Provisional application No. 63/497,837, filed on Apr. 24, 2023.

(51) Int. Cl. H01L 25/065; H01L 23/00; H01L 23/31; H01L 23/498

(52) U.S. Cl. CPC H01L 25/0657; H01L 23/3128; H01L 23/49816; H01L 24/05; H01L 24/13; H01L 2224/05009; H01L 2224/05025; H01L 2224/13009; H01L 2224/13025; H01L 2225/06513; H01L 2225/06562; H01L 2924/1306; H01L 2924/1434; H01L 2924/15311; H01L 2924/182

(57) ABSTRACT

A device includes an integrated device. The integrated device includes a die that is at least partially encapsulated. The die includes a conductive pad. The device also includes a first passivation layer coupled to a first surface of the die. The device includes an offset interconnect extending along a surface of the first passivation layer and including a portion that extends through an opening in the first passivation layer to contact the conductive pad. The device includes a bump including a portion that extends through an opening in a second passivation layer to contact the offset interconnect. The bump is offset, in a direction along a surface of the second passive layer, from the conductive pad.

### CROSS-REFERENCE TO RELATED APPLICATIONS

The present application claims priority from Provisional Patent Application No. 63/497,837, filed Apr. 24, 2023, entitled “INTEGRATED DEVICE COMPRISING AN OFFSET INTERCONNECT,” the content of which is incorporated herein by reference in its entirety.

### FIELD

Various features relate to integrated devices.

### BACKGROUND

Chip-package interaction (CPI) stress can occur at an interface between a semiconductor chip and its packaging. For example, during thermal processing, differences in the coefficients of thermal expansion between materials of a packaged chip can introduce CPI stresses, which can damage the chip or connections between the chip and packaging. Damage due to CPI stress can result in yield loss, reduced device reliability, shortened device lifetimes, etc.

### SUMMARY

Various features relate to integrated devices.

One example provides a device comprising an integrated device. The integrated device includes a die that is at least partially encapsulated. The die includes a conductive pad. The device includes a first passivation layer coupled to a first surface of the die. The device includes an offset interconnect extending along a surface of the first passivation layer and including a portion that extends through an opening in the first passivation layer to contact the conductive pad. The device includes a bump including a portion that extends through an opening in a second passivation layer to contact the offset interconnect. The bump is offset, in a direction along a surface of the second passive layer, from the conductive pad.

Another example provides an integrated device including a die that is at least partially encapsulated. The die includes a conductive pad and a first passivation layer coupled to a first surface of the die. The integrated device also includes an offset interconnect extending along a surface of the first passivation layer and including a portion that extends through the first passivation layer to contact the conductive pad. The integrated device includes a bump including a portion that extends through an opening in a second passivation layer to contact the offset interconnect. The bump is offset, in a direction along a surface of the second passive layer, from the conductive pad.

Another example provides a device comprising an integrated device. The integrated device comprises a die that is at least partially encapsulated. The die comprises a conductive pad. The device includes a passivation layer coupled to a surface of the dic. The device includes a bump electrically coupled to the conductive pad via an offset interconnect that transfers forces applied to the bump to the passivation layer.

Another example provides an integrated device comprising a die that is at least partially encapsulated. The die comprises a conductive pad. The integrated device includes a passivation layer coupled to a surface of the die. The integrated device includes a bump electrically coupled to the conductive pad via an offset interconnect that transfers forces applied to the bump to the passivation layer.

Another example provides a method for fabricating an integrated device. The method includes forming an offset interconnect. The offset interconnect includes a first portion and a second portion, where the first portion of the offset interconnect extends through an opening of a first passivation layer to contact a conductive pad of a die that is at least partially encapsulated, and the second portion of the offset interconnect extends in a horizontal direction away from the opening of the first passivation layer. The method includes forming a second passivation layer over the offset interconnect. The method includes forming an opening through the second passivation layer to expose at least part of the second portion of the offset interconnect. The method includes forming a bump including a first portion that extends through the opening in the second passivation layer to contact the second portion of the offset interconnect, where the bump is offset from the opening in first passivation layer such that a footprint of the bump does not overlap the opening.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a cross sectional profile view of an exemplary integrated device that includes an offset interconnect.

FIG. 2 illustrates a cross sectional profile view of an exemplary integrated device that includes an offset interconnect.

FIG. 3 illustrates a cross sectional profile view of an exemplary integrated device that includes an offset interconnect.

FIG. 4 (which extends across several pages) illustrates an exemplary sequence for fabricating an exemplary integrated device that includes an offset interconnect.

FIG. 5 illustrates an exemplary flow diagram of a method for fabricating an exemplary integrated device that includes an offset interconnect.

FIG. 6 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a device comprising an integrated device. The integrated device includes a die that is at least partially encapsulated. The die includes a conductive pad. The device includes a first passivation layer coupled to a first surface of the die. The device includes an offset interconnect extending along a surface of the first passivation layer and including a portion that extends through an opening in the first passivation layer to contact the conductive pad. The device includes a bump including a portion that extends through an opening in a second passivation layer to contact the offset interconnect. The bump is offset, in a direction along a surface of the second passive layer, from the conductive pad.

In a particular aspect, the offset interconnect is configured to at least partially mitigate transfer of chip-package interaction (CPI) stress from the bump to the die. CPI stress can occur at an interface between a semiconductor chip and its packaging during fabrication processes. During some fabrication processes, a packaged semiconductor chip is subjected to various thermal and mechanical stresses, which give rise to CPI stresses. For example, during thermal processing, differences in the coefficients of thermal expansion between materials can introduce CPI stresses. CPI stresses can damage the chip or connections between the chip and packaging, which can result in yield loss, reduced device reliability, and shortened device lifetimes. CPI stresses can be reduced by careful selection of materials, addition of redistribution layers or stress buffer layers, etc. However, relying on material selection limits design and manufacturing options, and adding layers to address CPI increases the size and cost of the packaged semiconductor chip.

In a particular aspect, the offset interconnect disclosed herein reduces CPI stresses, in part, by disrupting a stress transfer path between a bump and a conductive pad of a die. In some implementations, the offset interconnect is formed on the at least partially encapsulated die, rather than, for example, in a redistribution layer. Accordingly, the offset interconnect can be formed without adding additional layers or process steps.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

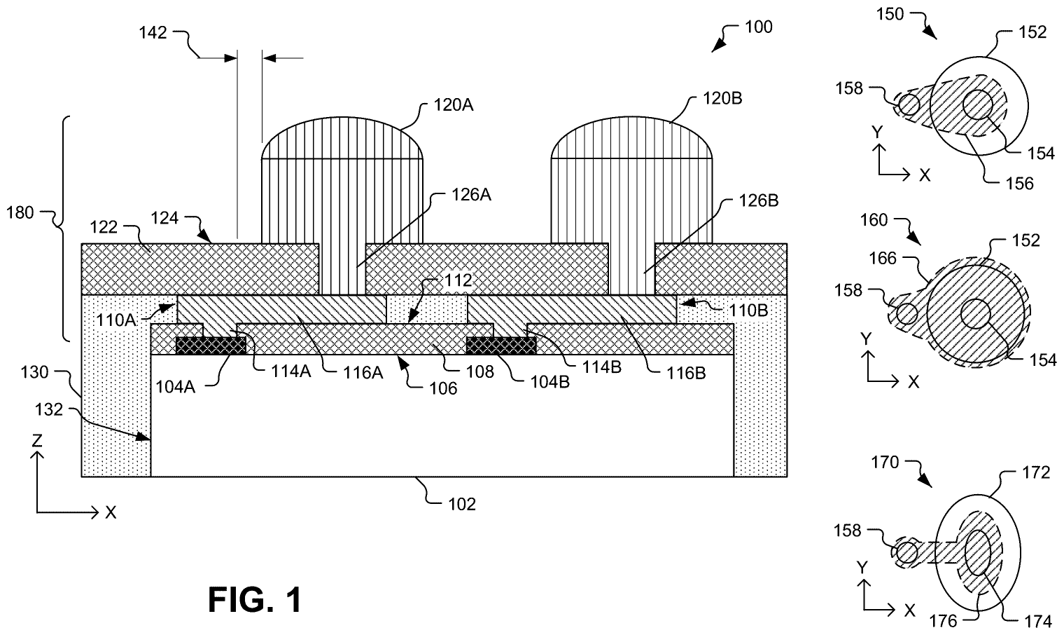

In some drawings, multiple instances of a particular type of feature are used. Although these features are physically and/or logically distinct, the same reference number is used for each, and the different instances are distinguished by addition of a letter to the reference number. When the features as a group or a type are referred to herein (e.g., when no particular one of the features is being referenced), the reference number is used without a distinguishing letter. However, when one particular feature of multiple features of the same type is referred to herein, the reference number is used with the distinguishing letter. For example, referring to FIG. 1, multiple conductive pads of a die 102 are illustrated and associated with reference numbers 104A and 104B. When referring to a particular one of these conductive pads, such as a conductive pad 104A, the distinguishing letter “A” is used. However, when referring to any arbitrary one of these conductive pads or to these conductive pads as a group, the reference number 104 is used without a distinguishing letter.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

### Exemplary Integrated Device Comprising An Offset Interconnect

FIG. 1 illustrates a cross sectional profile view of an integrated device 100 that includes an offset interconnect. The integrated device 100 includes a die 102 that is at least partially encapsulated. For example, the die 102 is at least partially encapsulated by mold 130 (e.g., cured mold compound) contacting one or more sidewalls 132 of the die 102 and a passivation layer (e.g., first passivation layer 108) contacting a first surface 106 of the die 102. For example, the at least partially encapsulated die 102 may correspond to a die of a reconstructed wafer.

The die 102 includes or corresponds to a semiconductor substrate (e.g., silicon (Si)) that has been processed to form an integrated circuit. To illustrate, the integrated circuit can include a plurality of transistors and/or other circuit elements arranged and interconnected to form logic cells, memory cells, etc. Components of the integrated circuit can be formed in and/or over the semiconductor substrate. Different implementations can use different types of transistors, such as a field effect transistor (FET), planar FET, finFET, a gate all around FET, or mixtures of transistor types. In some implementations, a front end of line (FEOL) process may be used to fabricate the integrated circuit in and/or over the semiconductor substrate.

The die 102 also includes or is coupled to one or more conductive pads 104 (e.g., conductive pads 104A and 104B) that enable circuit elements integrated in the die 102 to be connected to off-die circuits. For example, the conductive pads 104 may be configured to provide at least one electrical path for input/output (I/O) signals for the integrated device 100. The conductive pads 104 may be configured to provide at least one electrical path for power for the integrated device 100. The conductive pads 104 can also include testing pads and/or landing pads for testing probes. In some implementations, when viewed from above (e.g., along a Z axis), the conductive pads 104 may have rectangular, round, and/or elongated shapes.

In the example illustrated in FIG. 1, the first passivation layer 108 is disposed on (e.g., contacting) the first surface 106 of the die 102 and may partially cover one or more of the conductive pads 104. The first passivation layer 108 may be a hard passivation layer. The first passivation layer 108 may include a dielectric.

In addition to the die 102, the integrated device 100 includes an interconnect structure 180 coupled to (e.g., formed on one or more surfaces of) the die 102. In some implementations, one or more back end of line (BEOL) processes may be used to fabricate the interconnect structure 180. The interconnect structure 180 enables coupling the conductive pads 104 of the die 102 to external electrical connectors of the integrated device 100.

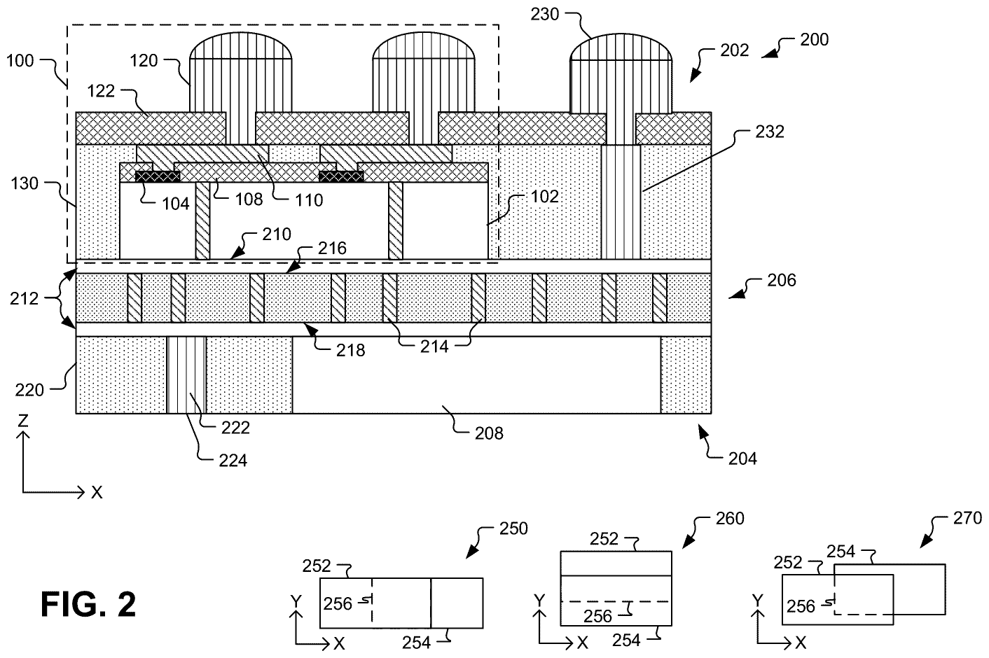

In the example illustrated in FIG. 1, the interconnect structure 180 includes bump(s) 120 (e.g., a bump 120A and a bump 120B), one or more offset interconnects 110 (e.g., offset interconnect 110A and 110B), and one or more protective layers overlying the die 102, such as the first passivation layer 108, mold 130, a second passivation layer 122, one or more additional protective layers, or combinations thereof. Although FIG. 1 illustrates the conductive pads 104 as distinct from the interconnect structure 180, in some implementations, the conductive pads 104 are considered part of the interconnect structure 180. In some implementations, one or more BEOL processes may be used to fabricate the mold 130, the first passivation layer 108, and openings in the first passivation layer 108 to access the conductive pads 104. The openings can have similar or different shapes. It is noted that a passivation layer (e.g. the first passivation layer 108, the second passivation layer 122, etc.) may be considered to have an opening even if the opening is subsequently filled and/or occupied by another material that is not the passivation layer. In some implementations, the interconnect structure 180 can also include other features and components. To illustrate, as described below with reference to FIG. 2, when multiple die are stacked, at least a portion of a conductive via enabling connection to another die can extend through a portion of the interconnect structure 180.

In FIG. 1, the bumps 120 can include or correspond to external electrical connectors of the integrated device 100. In a particular aspect, one or more of the bumps 120 includes a portion 126 that extends through an opening of the second passivation layer 122 to contact a respective one of the offset interconnects 110. For example, the bump 120A includes a portion 126A that extends through an opening in the second passivation layer 122 to contact the offset interconnect 110A, and the bump 120B includes a portion 126B that extends through an opening in the second passivation layer 122 to contact the offset interconnect 110B.

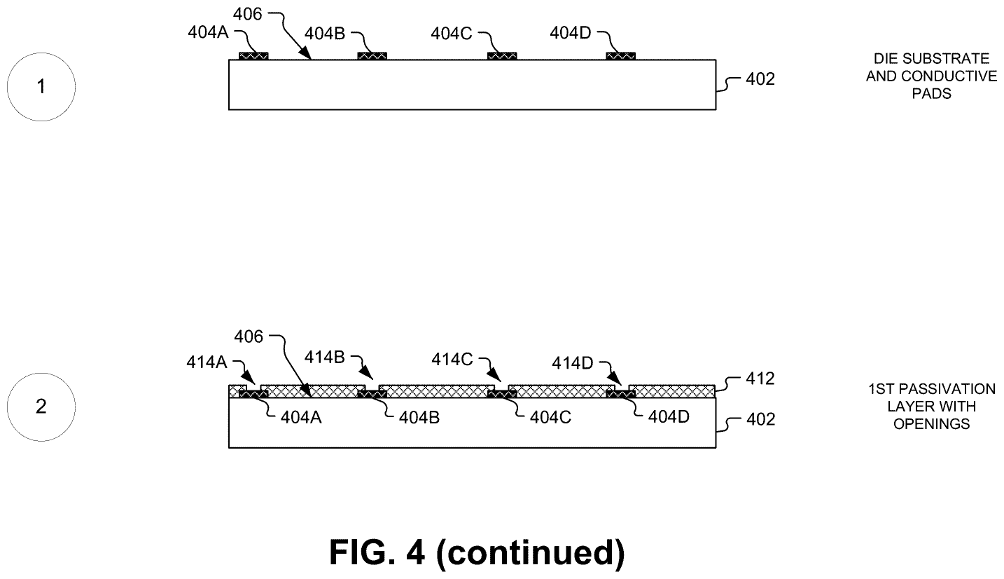

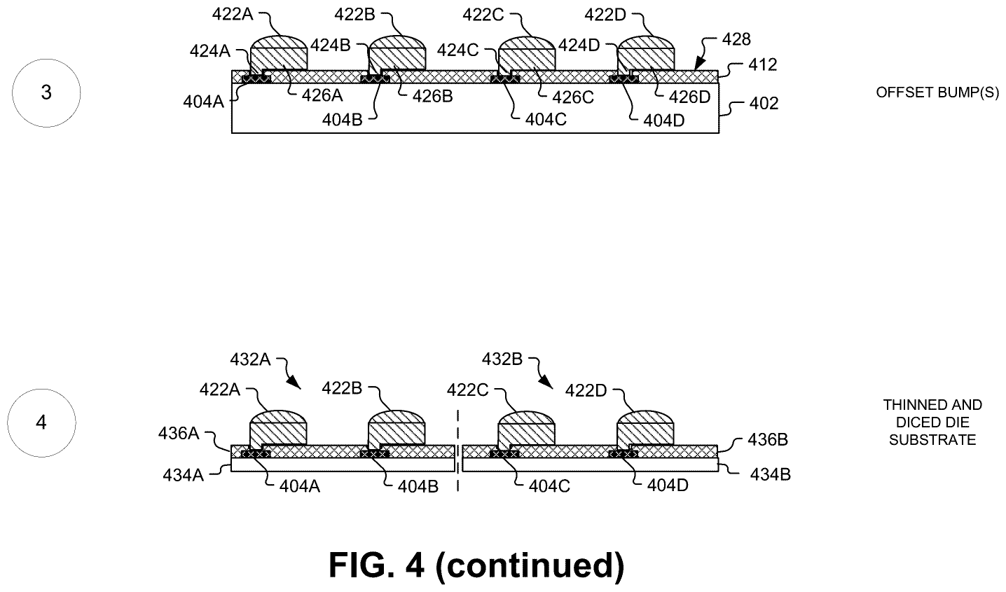

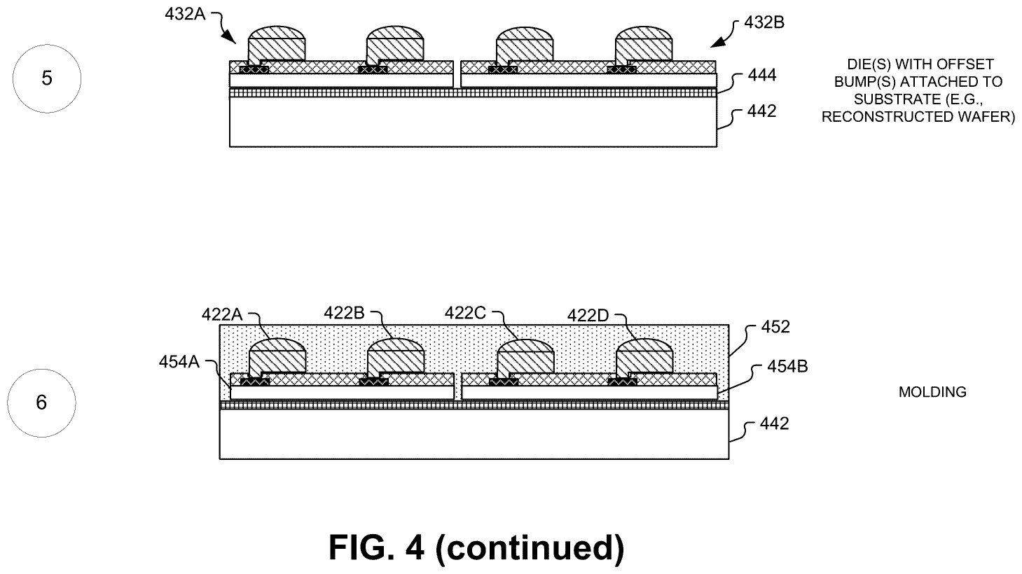

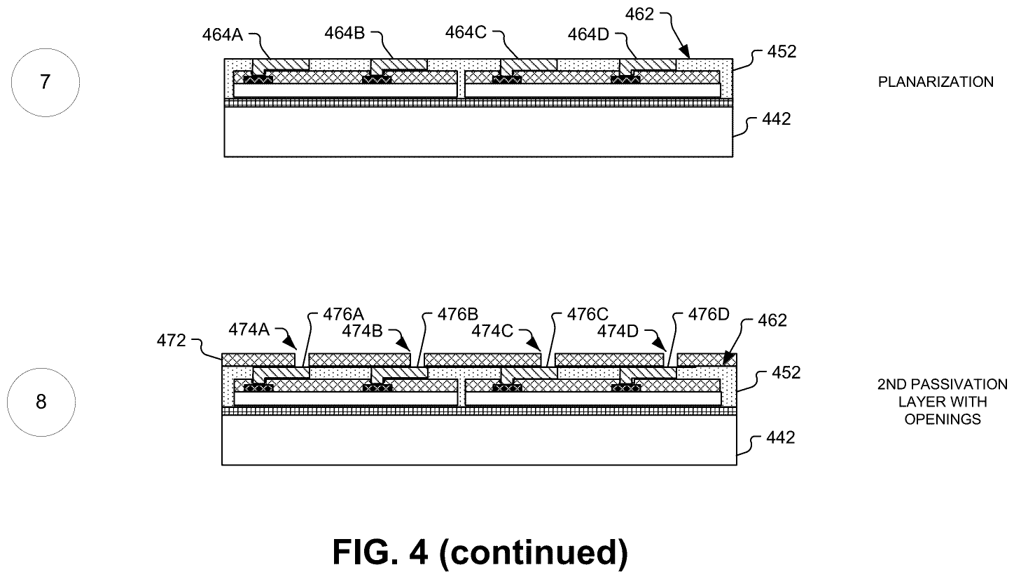

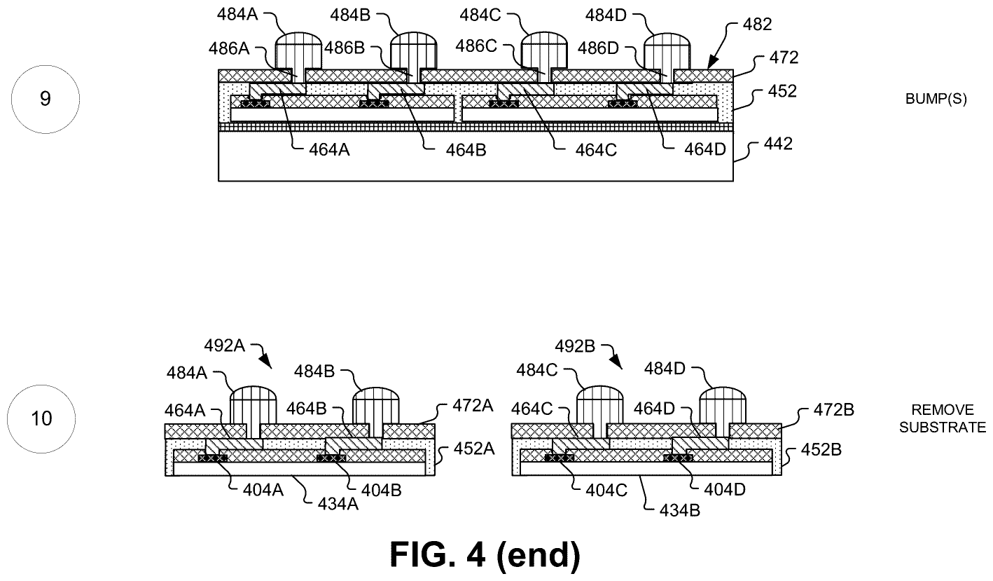

In a particular aspect, each of the offset interconnects 110 includes a portion 114 that extends through an opening in the first passivation layer 108 to contact a respective one of the conductive pads 104. For example, the offset interconnect 110A includes a portion 114A that extends through an opening in the first passivation layer 108 to contact the conductive pad 104A, and the offset interconnect 110B includes a portion 114B that extends through an opening in the first passivation layer 108 to contact the conductive pad 104B. Further, each of the offset interconnects 110 includes a portion 116 that extends along a surface 112 (e.g., in a horizontal direction in the orientation illustrated in FIG. 1) of the first passivation layer 108 away from the opening in the first passivation layer 108 through which the associated portion 114 extends. For example, the offset interconnect 110A includes a portion 116A that extends along the surface 112 of the first passivation layer 108 away from the portion 114A in a direction along an X axis, and the offset interconnect 110B includes a portion 116B that extends along the surface 112 of the first passivation layer 108 away from the portion 114B in a direction along the X axis. In a particular implementation, the offset interconnect 110 includes a remainder (e.g., a remaining portion) of an offset bump after a planarization operation removes an upper part of the offset bump and at least a portion of the mold 130 (as described further below, with reference to FIG. 4).

The portion 116 of an offset interconnect 110 contacts the portion 126 of a respective bump 120, and the portion 114 of the offset interconnect 110 contacts the conductive pad 104. Thus, the bump 120 is electrically coupled to the conductive pad 104 via the offset interconnect 110. The portion 116 of the offset interconnect 110 extends away from the portion 114 of the offset interconnect such that a footprint of the bump 120 connected to the portion 116 does not overlap the portion 114 of the offset interconnect 110. For example, portion 116A of the offset interconnect 110A extends away from the portion 114A sufficiently that the footprint of the bump 120A does not overlap the portion 114A (or an interface between the portion 114A and the conductive pad 104A). To illustrate, in FIG. 1, an edge of the bump 120A is offset by a distance 142 along the X axis from the opening through the first passivation layer 108 through which the portion 114A of the offset interconnect 110A extends.

Top views 150, 160, and 170 in FIG. 1 further illustrate examples of the disclosed offset interconnect scheme. The top view 150 illustrates a footprint 152 of one of the bumps 120 (e.g., an area of a surface 124 of the second passivation layer 122 that is covered by the bump 120), and a footprint 154 of the portion 126 of the bump 120 that extends through the second passivation layer 122. The top view 150 also illustrates a footprint 156 of the offset interconnect 110 (e.g., an area of the surface 112 of the first passivation layer 108 covered by the portion 116 of the offset interconnect 110), and a footprint 158 of an interface between the conductive pad 104 and the portion 114 of the offset interconnect 110 that extends through the first passivation layer 108.

In the example illustrated in the top view 150, the footprint 156 of the offset interconnect 110 has a teardrop shape. Additionally, in this example, the footprint 152 of the bump 120 has a circular shape, as do the footprint 154 of the portion 126 of the bump 120 that contacts the offset interconnect 110 and the footprint 158 of the interface between the conductive pad 104 and the portion 114 of the offset interconnect 110 that extends through the first passivation layer 108. As illustrated in the top view 150, the footprint 152 of the bump 120 does not overlap the footprint 158 of the interface between the conductive pad 104 and the portion 114 of the offset interconnect 110 that extends through the first passivation layer 108. For example, the footprint 156 of the offset interconnect 110 is elongated in a direction along the X axis such that the footprint 152 is offset from the footprint 158.

The top view 160 illustrates another example in which the offset interconnect 110 has a different shape, resulting a footprint 166 of the offset interconnect corresponding more closely with the footprint 152 of the bump 120 than in the example illustrated in the top view 150. In the top view 160, the footprint 152 of the bump 120 does not overlap the footprint 158 of the interface between the conductive pad 104 and the portion 114 of the offset interconnect 110 that extends through the first passivation layer 108. For example, the footprint 166 of the offset interconnect 110 extends in a direction along the X axis sufficiently that the footprint 152 is offset from the footprint 158.

The top view 170 illustrates another example in which the bump 120 and the portion 126 of the bump 120 that extends through the second passivation layer 122 to contact the offset interconnect 110 are not circular, resulting in a footprint 172 of the bump 120 and a footprint 174 of the portion 126 that are each oval or oblong. Additionally, as compared to the top views 150 and 160, in the top view 170, the footprint 176 of the offset interconnect 110 has a smaller area (e.g., uses less conductive material and less real estate) by more closely aligning with contours of the footprint 174 of the portion 126 and the footprint 158 of the interface between the conductive pad 104 and the portion 114 of the offset interconnect 110 that extends through the first passivation layer 108. In the top view 170, the footprint 172 of the bump 120 does not overlap the footprint 158 of the interface between the conductive pad 104 and the portion 114 of the offset interconnect 110 that extends through the first passivation layer 108. For example, the footprint 176 of the offset interconnect 110 extends in a direction along the X axis such that the footprint 172 is offset from the footprint 158.

The examples illustrated in the top views 150, 160, and 170 are illustrative and not limiting. For example, in some implementations, one or more of the offset interconnects 110 can have a footprint that extends in a direction along a Y axis or in a direction at an angle between the X and Y axes. Further, in some implementations, the integrated device 100 can include offset interconnects 110 that extend in different directions than one another. To illustrate, the offset interconnect 110A can extend in a direction along the X axis and the offset interconnect 110B can extend along a different direction, such as in a direction along the Y axis or in a direction angularly offset from both the X axis and the Y axis. In such implementations, the orientation and shape of each offset interconnect 110 can be selected such that the bump 120 connected to the offset interconnect 110 is disposed at a desired position on the integrated device 100 and such that the footprint of the bump 120 does not overlap the footprint of the interface between the conductive pad 104 and the portion 114 of the offset interconnect 110 that extends through the first passivation layer 108. Such implementations provide both improved CPI stress mitigation and flexibility in positioning external electrical connections (e.g., bumps 120) of the integrated device 100.

The offset interconnect(s) 110 are configured to at least partially mitigate transfer of CPI stress from the bump 120 to the conductive pad 104 and/or the die 102. For example, a force applied to the bump 120 (e.g., during a test operation or during an operation to electrically connect the integrated device 100 to another circuit) is substantially transferred to the first passivation layer 108 rather than directly to the conductive pad 104 and the die 102. Additionally, formation of an electrical connection from a bump 120 to a conductive pad 104 of a die 102 through openings in multiple passivation layers (e.g., the first passivation layer 108 and the second passivation layer 122) is often performed during BEOL operations. As such, formation of the offset interconnect(s) 110 does not by itself increase a count of layers of the integrated device 100 and does not significantly increase processing time.

Although the example illustrated in FIG. 1 includes two conductive pads 104 electrically coupled, via two offset interconnect 110, to two bumps 120, in other implementations, the integrated device 100 includes more than two conductive pads 104 electrically coupled, via respective offset interconnects 110, to respective bumps 120. In still other implementations, the integrated device 100 includes a single conductive pad 104 that is electrically coupled, via an offset interconnect 110, to a bump 120.

FIG. 2 illustrates a cross sectional profile view of an integrated device 200 that includes an offset interconnect. In the example illustrated in FIG. 2, the integrated device 200 includes the integrated device 100 coupled to one or more additional devices (e.g., a second die 208) in a stacked die configuration. For example, in FIG. 2, the integrated device 100 includes the die 102. The die 102 is at least partially encapsulated by mold 130. One or more conductive pads 104 are coupled to circuitry of the die 102. At least one of the conductive pad(s) 104 is connected to an offset interconnect 110 through an opening in a first passivation layer 108. A portion of the offset interconnect 110 extends in a direction (e.g., along the X axis in the orientation illustrated in FIG. 2) away from the opening in the first passivation layer 108 (e.g., away from an interface between the conductive pad 104 and the portion of the offset interconnect 110 contacting the conductive pad 104). A bump 120 is disposed on a second passivation layer 122. A portion of the bump 120 extends through an opening in the second passivation layer 122 to contact the offset interconnect 110. The offset interconnect 110 enables the bump 120 to be electrically coupled to the conductive pad 104 and physically arranged such that the bump 120 is offset from the conductive pad 104 (e.g., as described with reference to FIG. 1).

In the example illustrated in FIG. 2, a second side 210 of the die 102 is coupled to a first side 216 of one or more die-die interconnect layers 206. The second die 208 is coupled to a second side 218 of one or more die-die interconnect layers 206. Optionally, in some implementations, one or more redistribution layers 212 are disposed between the second side 210 of the die 102 and the first side 216 of one or more die-die interconnect layers 206. Additionally, or alternatively, one or more redistribution layers 212 can optionally be disposed between the second die 208 and the second side 218 of one or more die-die interconnect layers 206. The one or more die-die interconnect layers 206 include one or more conductors 214 (e.g., pillars, conductive vias, etc.) that provide at least one electrical path signal exchange between the die 102 and the second die 208, between the second die 208 and external electrical contacts (e.g., one or more of the bumps 120 or a bump 230) on a first side 202 (e.g., an external surface) of the integrated device 200, between the die 102 and one or more external electrical contacts (e.g., a contact 224) on a second side 204 of the integrated device 200, or a combination thereof.

In the example illustrated in FIG. 2, the bump 230 is disposed on the first side 202 of the integrated device 200 and extends through an opening in the second passivation layer 122 to contact a conductor 232 (e.g., a pillar, a conductive via, etc.). The conductor 232 extends through an opening in the mold 130 to the die-die interconnect layers 206 or the one or more redistribution layers 212. The bump 230 and conductor 232 can form a portion of a conductive path to provide signals from the first side 202 of the integrated device 200 to the second die 208 or to one or more contacts (e.g., the contact 224) on the second side 204 of the integrated device 200.

In the example illustrated in FIG. 2, the contact 224 corresponds to an exposed end of a conductor 222 that extends through an opening in mold 220 to the die-die interconnect layers 206 or the one or more redistribution layers 212. In other implementations, the contact 224 is distinct from but coupled to the conductor 222. The contact 224 and conductor 222 can form a portion of a conductive path to provide signals from the second side 204 of the integrated device 200 to the die 102 or to one or more external electrical contacts (e.g., the bumps 120 or 230) on the first side 202 of the integrated device 200.

Top views 250, 260, and 270 in FIG. 2 further illustrate additional features of the integrated device 200. The top view 250 illustrates a footprint 252 of the die 102 and a footprint 254 of the second die 208. As illustrated in the top view 250 the footprint 252 of the die 102 partially overlaps the footprint 254 of the second die 208 at an overlap region 256. For example, the die 102 is not disposed directly over the second die 208 such that no portion of the die 102 extends beyond the footprint 254 of the second die 208. Likewise, the second die 208 is not disposed directly under the die 102 such that no portion of the second die 208 extends beyond the footprint 252 of the die 102.

The top view 250 illustrates an example in which the die 102 and the second die 208 are stacked and offset from one another in a direction along the X axis. The top view 260 illustrates another example in which the die 102 and the second die 208 are stacked and offset from one another in a direction along the Y axis. The top view 270 illustrates yet another example in which the die 102 and the second die 208 are stacked and offset from one another in a direction at an angle between the X axis and the Y axis.

In the example illustrated in FIG. 2, the integrated device 200 includes two die (die 102 and second die 208) arranged in a stacked configuration. In other implementations, the integrated device 200 includes more than two die arranged in a stacked configuration.

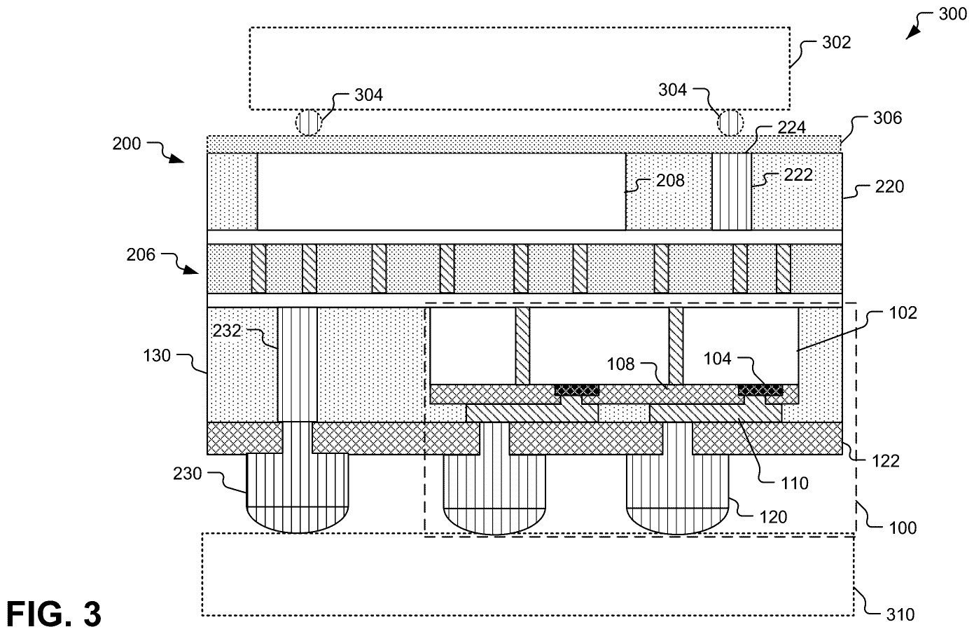

FIG. 3 illustrates a cross sectional profile view of an integrated device 300 that includes an offset interconnect. In the example illustrated in FIG. 3, the integrated device 300 includes the integrated device 200 coupled to one or more additional device 302 or circuits 310. For example, in FIG. 3, the integrated device 200 includes the integrated device 100, and the integrated device 100 includes the die 102, which is at least partially encapsulated by mold 130, and one or more conductive pads 104 coupled to circuitry of the die 102. At least one of the conductive pad(s) 104 is connected to an offset interconnect 110 through an opening in a first passivation layer 108. A portion of the offset interconnect 110 extends in a direction away from the opening in the first passivation layer 108 (e.g., away from an interface between the conductive pad 104 and the portion of the offset interconnect 110 contacting the conductive pad 104). A portion of a bump 120 disposed on a second passivation layer 122 extends through an opening in the second passivation layer 122 to contact the offset interconnect 110. The offset interconnect 110 enables the bump 120 to be electrically coupled to the conductive pad 104 and physically arranged such that the bump 120 is offset from the conductive pad 104 (e.g., as described with reference to FIG. 1).

The integrated device 200 of FIG. 3 also includes the second die 208 coupled, via one or more die-die interconnect layers 206, to the integrated device 100. The integrated device 200 of FIG. 3 optionally includes one or more redistribution layers (e.g., redistribution layer(s) 212 of FIG. 2) disposed between the die 102 and the die-die interconnect layer(s) 206, between the die 208 and the die-die interconnect layer(s) 206, or both.

In the example illustrated in FIG. 3, the integrated device 300 optionally includes the bump 230 and the conductor 232. In implementations of the integrated device 300 that include the bump 230 and the conductor 232, the bump 230 and conductor 232 can form a portion of a conductive path to provide signals from the second die 208 to the circuit(s) 310, from the circuit(s) 310 to the second die 208, or both.

In the example illustrated in FIG. 3, the integrated device 300 optionally includes the contact 224 and the conductor 222. In implementations of the integrated device 300 that include the contact 224 and the conductor 222, the contact 224 and the conductor 222 can form a portion of a conductive path to provide signals from the die 102 to the additional device(s) 302, from the additional device(s) 302 to the die 102, or both.

In implementations of the integrated device 300 that include the additional device(s) 302, the additional device(s) 302 can be coupled to the integrated device 200 via one or more redistribution layers 306. To illustrate, in FIG. 3, solder balls 304 or similar electrical connections can be provided between the integrated device 200 and the additional device(s) 302 or between the redistribution layer(s) 306 and the additional device(s) 302. In implementations of the integrated device 300 that include the circuit(s) 310, the integrated device 100 can be coupled to the circuit(s) 310 via one or more of the bumps 120.

In addition to the die(s) (e.g., the die 102, the die 208), one or more of the integrated devices 100, 200, and 300 may include a power management integrated circuit (PMIC). One or more of the integrated devices 100, 200, 300 may include an application processor. One or more of the integrated devices 100, 200, 300 integrated device may include a modem. One or more of the integrated devices 100, 200, 300 integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. One or more of the integrated devices 100, 200, 300 may include at least one electronic circuit (e.g., first electronic circuit, second electronic circuit, etc.) in addition to the dies (e.g., the die 102, the die 208, or both) and other layers described above with reference to FIGS. 1-3. An integrated device (e.g., one of the integrated devices 100, 200, 300) may be an example of an electrical component and/or electrical device.

In some implementations, a die (e.g., the die 102, the die 208, or both) of one or more of the integrated devices 100, 200, 300 can include a chiplet. A chiplet may be fabricated using one or more processes that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). Using several chiplets that perform several functions may reduce the overall cost of a package relative to using a single chip to perform all of the functions of a package.

### Exemplary Sequence for Fabricating an Integrated Device Comprising An Offset Interconnect

In some implementations, fabricating an integrated device (e.g., one or more of the integrated devices 100, 200, 300) includes several processes. FIG. 4 (which is continued across several pages) illustrates an exemplary sequence for providing or fabricating an integrated device with an offset interconnect. In some implementations, the sequence of FIG. 4 may be used to provide or during fabrication of one or more of the integrated devices 100, 200, 300 of FIGS. 1-3.

It should be noted that the sequence of FIG. 4 may combine one or more stages in order to simplify and/or clarify the sequence for providing or fabricating an integrated device. In some implementations, the order of the processes may be changed or modified. In some implementations, one or more of processes may be replaced or substituted without departing from the scope of the disclosure. In the following description, reference is made to various illustrative Stages of the sequence, which are numbered (using circled numbers) in FIG. 4.

Stage 1, as shown in FIG. 4, illustrates a state after a die substrate 402 with conductive pads 404 (including, for example, conductive pads 404A, 404B, 404C, and 404D) on a first surface of the die substrate 402. The conductive pads 404 may include, for example, testing pads, I/O pads, power interconnect pads, or other connectors to provide electrical connections to integrated circuit elements of the die substrate 402.

Providing the die substrate 402 and the conductive pads 404 may include fabricating the die substrate 402, fabricating and the conductive pads 404 on the die substrate 402, or both. The die substrate 402 and the conductive pads 404 may be fabricated using FEOL fabrication process, BEOL fabrication processes, or both. One or more of the conductive pads 404 can include or correspond to one or more of the conductive pads 104 of FIGS. 1-3.

Stage 2 illustrates a state after a first passivation layer 412 is formed on the surface 406 of the die substrate 402 and openings 414 (including, for example, openings 414A, 414B, 414C, and 414D) are formed through the first passivation layer 412. In a particular example, a deposition, a lamination, an exposure, a development and/or an etching process can be used to form the first passivation layer 412 and to provide the openings 414. One or more of the openings 414 exposes a portion of a conductive pad 404 under the first passivation layer 412. To illustrate, in FIG. 4, the opening 414A exposes at least a portion of the conductive pad 404A, the opening 414B exposes at least a portion of the conductive pad 404B, the opening 414C exposes at least a portion of the conductive pad 404C, and the opening 414D exposes at least a portion of the conductive pad 404D.

Stage 3 illustrates a state after offset bumps 422 (including, for example, offset bump 422A, offset bump 422B, offset bump 422C, and offset bump 422D) are formed. One or more plating processes and one or more patterning processes may be used to form the offset bumps 422.

Each of the offset bumps 422 includes a portion 424 that extends through one of the openings 414 in the first passivation layer 412 to contact a respective one of the conductive pads 404. For example, the offset bump 422A includes a portion 424A that extends through the opening 414A in the first passivation layer 412 to contact the conductive pad 404A, the offset bump 422B includes a portion 424B that extends through the opening 414B in the first passivation layer 412 to contact the conductive pad 404B, the offset bump 422C includes a portion 424C that extends through the opening 414C in the first passivation layer 412 to contact the conductive pad 404C, and the offset bump 422D includes a portion 424D that extends through the opening 414D in the first passivation layer 412 to contact the conductive pad 404D.

Additionally, each of the offset bumps 422 includes a portion 426 that extends along a surface 428 of the first passivation layer 412 away from the opening 414. For example, the offset bump 422A includes a portion 426A that extends along the surface 428 away from the opening 414A, the offset bump 422B includes a portion 426B that extends along the surface 428 away from the opening 414B, the offset bump 422C includes a portion 426C that extends along the surface 428 away from the opening 414C, and the offset bump 422D includes a portion 426D that extends along the surface 428 away from the opening 414D.

Stage 4 illustrates a state after thinning of the die substrate 402 and dicing the die substrate to separate dies 432 (including, for example, die 432A and die 432B) from one another. One or more grinding processes can be used to thin the die substrate 402, and one or more cutting operations can be used to separate dies 432 from one another.

In the example illustrated in FIG. 4, at Stage 4, the die 432A includes a portion 436A of the first passivation layer 412 coupled to a thinned substrate 434A. The die 432A also includes one or more of the conductive pads 404, and at least one of the conductive pads 404 of the die 432A is coupled to one of the offset bumps. To illustrate, in the example illustrated in FIG. 4, the die 432A includes the conductive pad 404A coupled to the offset bump 422A and the conductive pad 404B coupled to the offset bump 422B. Similarly, in the example illustrated in FIG. 4, the die 432B includes a portion 436B of the first passivation layer 412 coupled to a thinned substrate 434B and includes the conductive pad 404C coupled to the offset bump 422C and the conductive pad 404D coupled to the offset bump 422D. It should be understood that, although FIG. 4 shows two die 432, each having two offset bumps 422, in many implementations, the die substrate 402 can be processed (as described above) to generate more than two die 432, and each of the dies 432 can include more than two offset bumps 422 or fewer than two (i.e., one) offset bumps 422.

Stage 5 illustrates a state after attaching the die(s) 432 to another substrate (substrate 442 in FIG. 4). One or more pick and place processes and die attach processes can be used to attach the die(s) 432 to the substrate 442. For example, the die(s) 432 can be attached to the substrate 442 using an adhesive layer 444. In some examples, attaching the die(s) 432 to the substrate 442 is referred to as a wafer reconstruction process, and the substrate 442 with the die(s) 432 attached is referred to as a reconstructed wafer.

Stage 6 illustrates a state after forming a mold 452 to at least partially encapsulate the die(s) 432. One or more molding processes can be used to form the mold 452. For example, a molding compound, or other infill material, can be applied in a layer that covers the die(s) 432 and contacts one or more sidewalls 454 of each die 432, and the layer can be cured to form the mold 452.

Stage 7 illustrates a state after planarization to form offset interconnects 464. One or more grinding processes can be used to remove a portion of the mold 452 and an upper part of each of the bumps 422 such that a remainder of each bump 422 (e.g., a planarized bump) corresponds to an offset interconnect 464. For example, an offset interconnect 464A corresponds to a remainder of the bump 422A after removal of an upper portion of the bump 422A, an offset interconnect 464B corresponds to a remainder of the bump 422B after removal of an upper portion of the bump 422B, an offset interconnect 464C corresponds to a remainder of the bump 422C after removal of an upper portion of the bump 422C, and an offset interconnect 464D corresponds to a remainder of the bump 422D after removal of an upper portion of the bump 422D. After the planarization process, a surface 462 of the mold 452 is substantially coplanar with an upper surface of each of the offset interconnects 464.

Stage 8 illustrates a state after a second passivation layer 472 is formed on the surface 482 and openings 474 (including, for example, openings 474A, 474B, 474C, and 474D) are formed through the second passivation layer 472. In a particular example, a deposition, a lamination, an exposure, a development and/or an etching process can be used to form the second passivation layer 472 and to provide the openings 474. One or more of the openings 474 exposes a portion 476 of an offset interconnect 464 under the second passivation layer 472. To illustrate, in FIG. 4, the opening 474A exposes a portion 476A of the offset interconnect 464A, the opening 474B exposes a portion 476B of the offset interconnect 464B, the opening 474C exposes a portion 476C of the offset interconnect 464C, and the opening 474D exposes a portion 476D of the offset interconnect 464D.

Stage 9 illustrates a state after bumps 484 (including, for example, bump 484A, bump 484B, bump 484C, and bump 484D) are formed. One or more plating processes and one or more patterning processes may be used to form the bumps 484.

Each of the bumps 484 includes a portion 486 that extends through one of the openings 474 in the second passivation layer 472 to contact a respective one of the offset interconnects 464. For example, the bump 484A includes a portion 486A that extends through the opening 474A to contact the offset interconnect 464A, the bump 484B includes a portion 486B that extends through the opening 474B to contact the offset interconnect 464B, the bump 484C includes a portion 486C that extends through the opening 474C to contact the offset interconnect 464C, and the bump 484D includes a portion 486D that extends through the opening 474D to contact the offset interconnect 464D.

In a particular aspect, each of the bumps 484 is offset from an interface between the offset interconnect 464 and conductive pad 404 to which the bump 484 is electrically connected. For example, a footprint of the bump 484A does not overlap a footprint of the portion 424A of the offset interconnect 464A attached to the conductive pad 404A, a footprint of the bump 484B does not overlap a footprint of the portion 424B of the offset interconnect 464B attached to the conductive pad 404B, a footprint of the bump 484C does not overlap a footprint of the portion 424C of the offset interconnect 464C attached to the conductive pad 404C, and a footprint of the bump 484D does not overlap a footprint of the portion 424D of the offset interconnect 464D attached to the conductive pad 404D. Accordingly, the offset interconnects 464 can at least partially mitigate transfer of CPI stress between the bumps 484 and the dies 432.

Stage 10 illustrates a state after removal of the substrate 442 and separation of integrated devices 492 (including, for example, integrated device 492A and integrated device 492B) from one another. One or more delamination processes can be used to remove the integrated devices 492 from the substrate 442, and one or more cutting operations can be used to separate integrated devices 492 from one another.

In a particular aspect, each of the integrated devices 492 can correspond to an instance of the integrated device 100 of FIG. 1. For example, the integrated device 492A includes a die 432A, which can correspond to an instance of the die 102 of FIG. 1. The die 432A is at least partially encapsulated by mold 452A, which can correspond to an example of the mold 130. The die 432A is coupled to or includes conductive pads 404A and 404B, which can correspond to examples of the conductive pads 104A and 104B of FIG. 1. The conductive pads 404A and 404B are coupled, respectively, to offset interconnects 464A and 464B, which can correspond to examples of the offset interconnects 110A and 110B, respectively, of FIG. 1. The offset interconnects 464A and 464B are coupled, respectively, to bumps 484A and 484B, which can correspond to examples of the bumps 120A and 120B, respectively, of FIG. 1.

### Exemplary Flow Diagram of a Method for Fabricating an Integrated Device Comprising Offset Interconnects

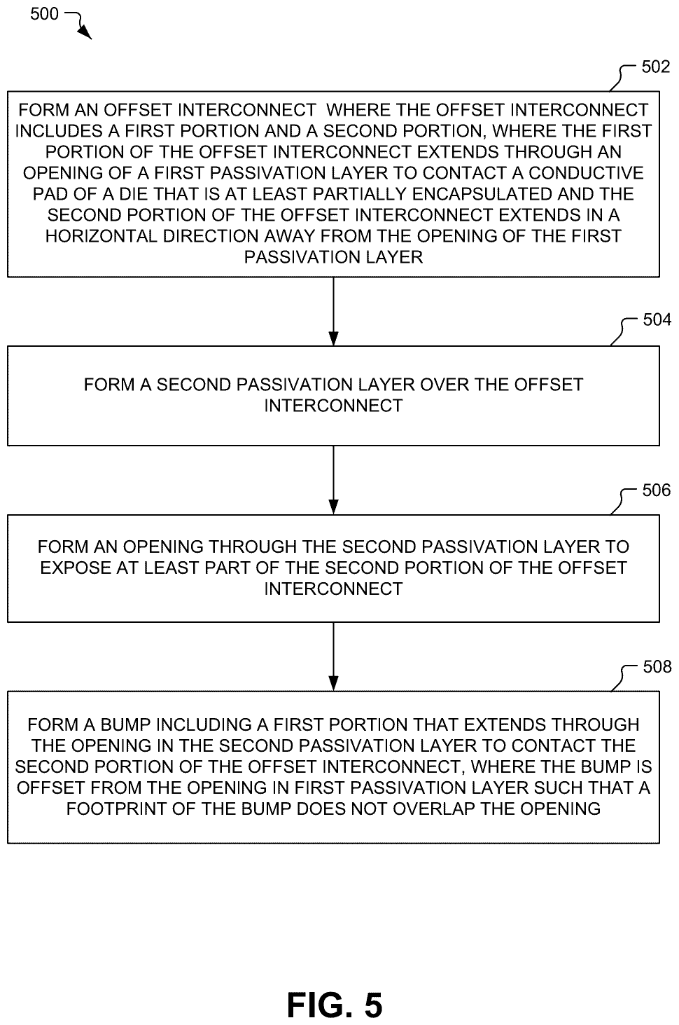

In some implementations, fabricating an integrated device includes several processes. FIG. 5 illustrates an exemplary flow diagram of a method 500 for providing or fabricating an integrated device. In some implementations, the method 500 of FIG. 5 may be used to provide or fabricate the integrated device 100 of FIG. 1.

It should be noted that the method 500 of FIG. 5 may combine one or more processes in order to simplify and/or clarify the method for providing or fabricating an integrated device. In some implementations, the order of the processes may be changed or modified.

The method 500 includes, at block 502, forming an offset interconnect, where the offset interconnect includes a first portion and a second portion. The first portion of the offset interconnect extends through an opening of a first passivation layer to contact a conductive pad of a die that is at least partially encapsulated and the second portion of the offset interconnect extends in a horizontal direction away from the opening of the first passivation layer. For example, the offset interconnect can be fabricated using one or more FEOL fabrication processes, one or more BEOL fabrication processes, or a combination thereof. In some implementations, Stage 7 of FIG. 4, illustrates and describes an example of an offset interconnect that includes a first portion and a second portion, where a first portion of the offset interconnect extends through an opening of a first passivation layer to contact a conductive pad of a die that is at least partially encapsulated and the second portion of the offset interconnect extends in a horizontal direction away from the opening of the first passivation layer.

In some implementations, forming the offset interconnect includes depositing a conductive material over the first passivation layer to form a second bump. For example, as described with reference to Stage 3 of FIG. 4, a plating process can be used to form an offset bump 422 (e.g., the second bump formed to the first passivation layer). In this example, the second bump includes a portion 424 that extends through an opening 414 of the first passivation layer 412 to contact a conductive pad 404. In such implementations, forming the offset interconnect can also include removing an upper part of the second bump. For example, as described with reference to Stage 7 of FIG. 4, an upper portion of the bump 422 can be removed (along with a portion of the mold 452) to form the offset interconnect 464.

The method 500 includes, at block 504, forming a second passivation layer over the offset interconnect, and at block 506, forming an opening through the second passivation layer to expose at least part of the second portion of the offset interconnect. Stage 8 of FIG. 4, illustrates and describes an example of the second passivation layer 472 that is formed over the offset interconnect 464 and openings 474 in the second passivation layer 472. One or more deposition processes, one or more lamination processes, one or more exposure processes, one or more development processes and/or one or more etching processes may be used to form and pattern the passivation layer 472.

The method 500 includes, at block 508, forming a bump including a first portion that extends through the opening in the second passivation layer to contact the second portion of the offset interconnect, where the bump is offset from the opening in first passivation layer such that a footprint of the bump does not overlap the opening in first passivation layer. Stage 9 of FIG. 4, illustrates and describes an example of forming the bump 484, which includes the portion 486 that extends through the opening 474 in the second passivation layer 472. The bump 484 is offset from the opening 414 in the first passivation layer 412 such that a footprint of the bump 484 does not overlap the opening 414.

In some implementations, the method 500 also includes coupling the integrated device to a second integrated device. For example, the integrated device 100 can be coupled to the die 208 to form the integrated device 200 of FIG. 2. As another example, the integrated device 200 can be coupled to the additional device(s) 302 to form the integrated device 300 of FIG. 3. In some implementations, the method 500 also includes coupling the integrated device to a circuit via the bump. For example, the integrated device 100 can be coupled to the circuit 310 using the bump(s) 120.

### Exemplary Electronic Devices

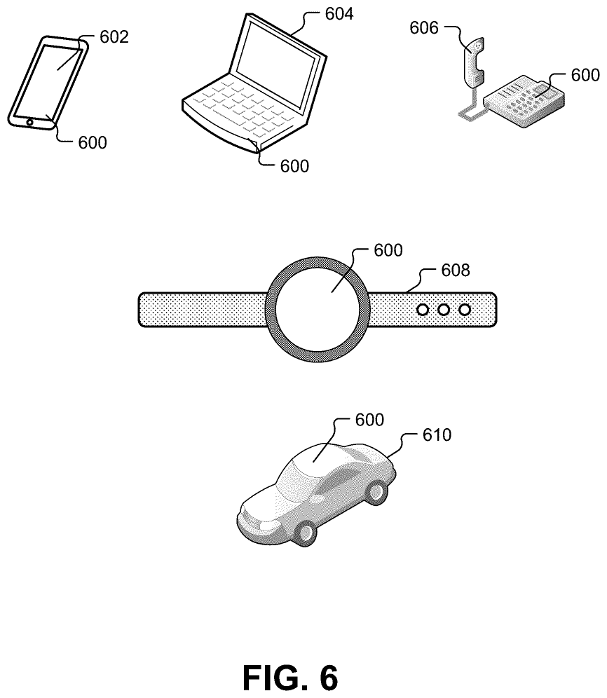

FIG. 6 illustrates various electronic devices that may include or be integrated with any of the integrated devices 100, 200, or 300. For example, a mobile phone device 602, a laptop computer device 604, a fixed location terminal device 606, a wearable device 608, or a vehicle 610 (e.g., an automobile or an aerial device) may include a device 600. The device 600 can include, for example, any of the devices and/or integrated circuit (IC) packages described herein, such as any of the integrated devices 100, 200, or 300. The devices 602, 604, 606 and 608 and the vehicle 610 illustrated in FIG. 6 are merely exemplary. Other electronic devices may also feature the device 600 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

One or more of the components, processes, features, and/or functions illustrated in FIGS. 1-6 may be rearranged and/or combined into a single component, process, feature or function or embodied in several components, processes, or functions. Additional elements, components, processes, and/or functions may also be added without departing from the disclosure. It should also be noted FIGS. 1-6 and its corresponding description in the present disclosure is not limited to dies and/or ICs. In some implementations, FIGS. 1-6 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (POP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, a device includes an integrated device that includes a die that is at least partially encapsulated, the die comprising a conductive pad; a first passivation layer coupled to a first surface of the die; an offset interconnect extending along a surface of the first passivation layer and including a portion that extends through an opening in the first passivation layer to contact the conductive pad; and a bump including a portion that extends through an opening in a second passivation layer to contact the offset interconnect, wherein the bump is offset, in a direction along a surface of the second passive layer, from the conductive pad.

Example 2 includes the device of Example 1, wherein the offset interconnect is configured to at least partially mitigate transfer of chip-package interaction (CPI) stress from the bump to the die.

Example 3 includes the device of Example 1 or Example 2, further comprising mold contacting one or more sidewalls of the die, at least a portion of the first passivation layer, and at least a portion of the offset interconnect.

Example 4 includes the device of any of Examples 1 to 3, wherein the offset interconnect comprises a portion of a planarized bump.

Example 5 includes the device of any of Examples 1 to 4, wherein the offset interconnect extends away from the conductive pad in a horizontal direction.

Example 6 includes the device of Example 5, wherein the offset interconnect extends along the horizontal direction such that a footprint of the bump and a footprint of the portion of the offset interconnect that extends through the opening in the first passivation layer do not overlap.

Example 7 includes the device of any of Examples 1 to 6, wherein the surface of the second passivation layer corresponds to an external surface of the integrated device, and the bump is an external electrical contact of the integrated device.

Example 8 includes the device of Example 7 and further includes a second integrated device coupled to the external electrical contact.

Example 9 includes the device of any of Examples 1 to 8, and further includes a substrate; and one or more additional dies, wherein the die and the one or more additional dies are coupled to the substrate.

Example 10 includes the device of Example 9, and further includes mold coupled to the substrate, to the die, and to the one or more additional dies; and an offset bump planarized with the mold to form the offset interconnect.

Example 11 includes the device of any of Examples 1 to 10, wherein the conductive pad is disposed on a first side of the die, and further includes a die interconnect layer having a first side; a second side of the die coupled to the first side of the die interconnect layer; and a second die coupled to a second side of the die interconnect layer.

Example 12 includes the device of Example 11, wherein the die at least partially overlaps the second die.

According to Example 13, an integrated device includes a die that is at least partially encapsulated, the die comprising a conductive pad; a first passivation layer coupled to a first surface of the die; an offset interconnect extending along a surface of the first passivation layer and including a portion that extends through an opening in the first passivation layer to contact the conductive pad; and a bump including a portion that extends through an opening in a second passivation layer to contact the offset interconnect, wherein the bump is offset, in a direction along a surface of the second passive layer, from the conductive pad.

Example 14 includes the integrated device of Example 13, wherein the offset interconnect is configured to at least partially mitigate transfer of chip-package interaction (CPI) stress from the bump to the die.

Example 15 includes the integrated device of Example 12 or Example 13, further comprising mold contacting one or more sidewalls of the die, at least a portion of the first passivation layer, and at least a portion of the offset interconnect.

Example 16 includes the integrated device of any of Examples 13 to 15, wherein the offset interconnect comprises a portion of a planarized bump.

Example 17 includes the integrated device of any of Examples 13 to 16, wherein the offset interconnect extends away from the conductive pad in a horizontal direction.

Example 18 includes the integrated device of Example 17, wherein the offset interconnect extends along the horizontal direction such that a footprint of the bump and a footprint of the portion of the offset interconnect that extends through the opening in the first passivation layer do not overlap.

Example 19 includes the integrated device of any of Examples 13 to 18, wherein the surface of the second passivation layer corresponds to an external surface of the integrated device, and the bump is an external electrical contact of the integrated device.

Example 20 includes the integrated device of Example 19 and further includes a second integrated device coupled to the external electrical contact.

According to Example 21, a device includes an integrated device that includes a die that is at least partially encapsulated, the die comprising a conductive pad; a passivation layer coupled to a surface of the die; and a bump electrically coupled to the conductive pad via an offset interconnect structure that transfers forces applied to the bump to the passivation layer.

Example 22 includes the device of Example 21, wherein the offset interconnect structure at least partially mitigates transfer of chip-package interaction (CPI) stress from the bump to the die.

Example 23 includes the device of Example 21 or Example 22, wherein the offset interconnect structure comprises: a first portion that extends through an opening in the passivation layer to contact the conductive pad; and a second portion that extends along a surface of the passivation layer to connect to a portion of the bump.

Example 24 includes the device of any of Examples 21 to 23 and further includes a second passivation layer, wherein the bump includes a portion that extends through an opening in the second passivation layer to contact the offset interconnect structure.

Example 25 includes the device of any of Examples 21 to 24 and further includes mold contacting one or more sidewalls of the die, at least a portion of the passivation layer, and at least a portion of the offset interconnect structure.

Example 26 includes the device of any of Examples 21 to 25, wherein the offset interconnect structure comprises a remainder of a planarized bump.

Example 27 includes the device of any of Examples 21 to 26, wherein the offset interconnect structure extends away from the conductive pad in a horizontal direction such that a footprint of the bump does not overlap a footprint of an interface between the offset interconnect structure and the conductive pad.

Example 28 includes the device of any of Examples 21 to 27, wherein the bump is an external electrical contact of the integrated device.

Example 29 includes the device of Example 28 and further includes a second integrated device including one or more external electrical connectors coupled to the external electrical contact.

Example 30 includes the device of any of Examples 21 to 29, further includes a substrate; and one or more additional dies, wherein the die and the one or more additional dies are coupled to the substrate and separated by mold.

Example 31 includes the device of any of Examples 21 to 30, and further includes a die interconnect layer having a first side; a second side of the die coupled to the first side of the die interconnect layer; and a second die coupled to a second side of the die interconnect layer.

Example 32 includes the device of Example 31, wherein the die at least partially overlaps the second die.

According to Example 33, an integrated device includes a die that is at least partially encapsulated, the die comprising a conductive pad; a passivation layer coupled to a surface of the die; and a bump electrically coupled to the conductive pad via an offset interconnect structure that transfers forces applied to the bump to the passivation layer.

Example 34 includes the integrated device of Example 33, wherein the offset interconnect structure at least partially mitigates transfer of chip-package interaction (CPI) stress from the bump to the die.

Example 35 includes the integrated device of Example 33 or Example 34, wherein the offset interconnect structure comprises: a first portion that extends through an opening in the passivation layer to contact the conductive pad; and a second portion that extends along a surface of the passivation layer to connect to a portion of the bump.

Example 36 includes the integrated device of any of Examples 33 to 35 and further includes a second passivation layer, wherein the bump includes a portion that extends through an opening in the second passivation layer to contact the offset interconnect structure.

Example 37 includes the integrated device of any of Examples 33 to 36 and further includes mold contacting one or more sidewalls of the die, at least a portion of the passivation layer, and at least a portion of the offset interconnect structure.

Example 38 includes the integrated device of any of Examples 33 to 37, wherein the offset interconnect structure comprises a remainder of a planarized bump.

Example 39 includes the integrated device of any of Examples 33 to 38, wherein the offset interconnect structure extends away from the conductive pad in a horizontal direction such that a footprint of the bump does not overlap a footprint of an interface between the offset interconnect structure and the conductive pad.

Example 40 includes the integrated device of any of Examples 33 to 39, wherein the bump is an external electrical contact of the integrated device.

According to Example 41, a method includes forming an offset interconnect structure, wherein the offset interconnect structure includes a first portion and a second portion, wherein the first portion of the offset interconnect structure extends through an opening of a first passivation layer to contact a conductive pad of a die that is at least partially encapsulated and the second portion of the offset interconnect structure extends in a horizontal direction away from the opening of the first passivation layer; forming a second passivation layer over the offset interconnect structure; forming an opening through the second passivation layer to expose at least part of the second portion of the offset interconnect structure; and forming a bump including a first portion that extends through the opening in the second passivation layer to contact the second portion of the offset interconnect structure, wherein the bump is offset from the opening in first passivation layer such that a footprint of the bump does not overlap the opening.

Example 42 includes the method of Example 41, further comprising coupling the die to another die.

Example 43 includes the method of Example 41 or Example 42, further comprising coupling the die to a circuit via the bump.

Example 44 includes the method of any of Examples 41 to 43, wherein the offset interconnect structure is configured to at least partially mitigate transfer of chip-package interaction (CPI) stress from the bump to the die.

Example 45 includes the method of any of Examples 41 to 44, wherein forming the offset interconnect structure comprises: depositing a conductive material over the first passivation layer to form a second bump, the second bump including the portion of the offset interconnect structure that extends through the opening of the first passivation layer to contact the conductive pad; and removing an upper part of the second bump.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. A device comprising:
a die that is at least partially encapsulated, the die comprising a conductive pad;
a first passivation layer coupled to a first surface of the die;
an offset interconnect extending along a surface of the first passivation layer and including a portion that extends through an opening in the first passivation layer to contact the conductive pad; and
a bump including a portion that extends through an opening in a second passivation layer to contact the offset interconnect, wherein the bump is offset, in a direction along a surface of the second passive layer, from the conductive pad.

2. The device of claim 1, wherein the offset interconnect is configured to at least partially mitigate transfer of chip-package interaction (CPI) stress from the bump to the die.

3. The device of claim 1, further comprising mold contacting one or more sidewalls of the die, at least a portion of the first passivation layer, and at least a portion of the offset interconnect.

4. The device of claim 1, wherein the offset interconnect comprises a portion of a planarized bump.

5. The device of claim 1, wherein the offset interconnect extends away from the conductive pad in a horizontal direction.

6. The device of claim 5, wherein the offset interconnect extends along the horizontal direction such that a footprint of the bump and a footprint of the portion of the offset interconnect that extends through the opening in the first passivation layer do not overlap.

7. The device of claim 1, further comprising:
a substrate; and
one or more additional dies, wherein the die and the one or more additional dies are coupled to the substrate.

8. The device of claim 7, further comprising:
mold coupled to the substrate, to the die, and to the one or more additional dies; and
an offset bump planarized with the mold to form the offset interconnect.

9. The device of claim 1, wherein the conductive pad is disposed on a first side of the die, and further comprising:
a die interconnect layer having a first side;
a second side of the die coupled to the first side of the die interconnect layer; and
a second die coupled to a second side of the die interconnect layer.

10. The device of claim 9, wherein the die at least partially overlaps the second die.

11. A device comprising:
a die that is at least partially encapsulated, the die comprising a conductive pad;
a passivation layer coupled to a surface of the die; and
a bump electrically coupled to the conductive pad via an offset interconnect that is configured to transfer forces applied to the bump to the passivation layer.

12. The device of claim 11, wherein the offset interconnect comprises:
a first portion that extends through an opening in the passivation layer to contact the conductive pad; and
a second portion that extends along a surface of the passivation layer to connect to a portion of the bump.

13. The device of claim 11, further comprising a second passivation layer, wherein the bump includes a portion that extends through an opening in the second passivation layer to contact the offset interconnect.

14. The device of claim 11, further comprising mold contacting one or more sidewalls of the die, at least a portion of the passivation layer, and at least a portion of the offset interconnect.

15. The device of claim 11, wherein the offset interconnect extends away from the conductive pad in a horizontal direction such that a footprint of the bump does not overlap a footprint of an interface between the offset interconnect and the conductive pad.

16. The device of claim 11, further comprising:
a substrate; and
one or more additional dies, wherein the die and the one or more additional dies are coupled to the substrate and separated by mold.

17. The device of claim 11, further comprising:
a die interconnect layer having a first side;
a second side of the die coupled to the first side of the die interconnect layer; and
a second die coupled to a second side of the die interconnect layer.

18. The device of claim 17, wherein the die at least partially overlaps the second die.

19. A method comprising:
forming an offset interconnect, wherein the offset interconnect includes a first portion and a second portion, wherein the first portion of the offset interconnect extends through an opening of a first passivation layer to contact a conductive pad of a die that is at least partially encapsulated and the second portion of the offset interconnect extends in a horizontal direction away from the opening of the first passivation layer;
forming a second passivation layer over the offset interconnect;
forming an opening through the second passivation layer to expose at least part of the second portion of the offset interconnect; and
forming a bump including a first portion that extends through the opening in the second passivation layer to contact the second portion of the offset interconnect, wherein the bump is offset from the opening in the first passivation layer such that a footprint of the bump does not overlap the opening in the first passivation layer.

20. The method of claim 19, wherein forming the offset interconnect comprises:
depositing a conductive material over the first passivation layer to form a second bump, the second bump including the first portion of the offset interconnect that extends through the opening of the first passivation layer to contact the conductive pad; and
removing an upper part of the second bump.
